(19) United States
(12) Patent Application Publication
(10) Pub. No.: US 2026/0206363 A1
(43) Pub. Date: Jul. 16, 2026

(54) MICRO-LED WAFER BONDING METHOD

(71) Applicant: SHANGHAI UNIVERSITY, Shanghai (CN)

(72) Inventors: Jianhua ZHANG, Shanghai (CN); Luqiao YIN, Shanghai (CN); Xiaoxiao JI, Shanghai (CN); Bingjun LI, Shanghai (CN)

(21) Appl. No.: 19/266,797

(22) Filed: Jul. 11, 2025

Related U.S. Application Data
(63) Continuation-in-part of application No. PCT/CN2025/073173, filed on Jan. 20, 2025.

(30) Foreign Application Priority Data
Jan. 14, 2025 (CN) 202510058721.6

(51) Int. Cl. H10H 20/01; H10H 20/812

(52) U.S. Cl. CPC H10H 20/018; H10H 20/017; H10H 20/032; H10H 20/0364; H10H 20/01335; H10H 20/812

(57) ABSTRACT

Provided is a micro-light-emitting diode (micro-LED) wafer bonding method, including: preparing an epitaxial wafer including a substrate layer and a pixel layer, and a driver substrate; conducting vapor deposition of a metal layer on the pixel layer to form a p electrode, and conducting vapor deposition of a bonding layer on the driver substrate; bonding the metal layer with the bonding layer, and peeling off the substrate layer; forming micro-LED pixels by etching; conducting vapor deposition of metal Ti, and repairing sidewalls of the micro-LED pixels by photoelectrochemical etching; step 6: removing the metal Ti, and conducting vapor deposition of a first passivation layer; forming a first opening; step 8: etching away metal material in the bonding layer; conducting vapor deposition of a second passivation layer; and conducting vapor deposition of an interconnection layer, where the interconnection layer and the driver substrate are interconnected to obtain an n electrode.

### CROSS REFERENCE TO RELATED APPLICATION

The present application is a continuation-in-part application of International Patent Application No. PCT/CN 2025/073173, filed on Jan. 20, 2025, which claims priority to Chinese Patent Application No. 2025100587216, entitled “MICRO-LED WAFER BONDING METHOD”, and filed with the China National Intellectual Property Administration on Jan. 14, 2025. The disclosure of the two applications is incorporated by references herein in their entireties as part of the present application.

### TECHNICAL FIELD

The present disclosure relates to the technical field of displays, and in particular to a micro-light-emitting diode (micro-LED) wafer bonding method.

### BACKGROUND

Compared with the traditional liquid crystal display (LCD) technology, micro-LED array display technology could achieve darker black, higher color saturation and better display effect due to the fact that each micro-LED pixel is an individual light-emitting unit capable of emitting light independently without relying on backlight. As the size of each micro-LED pixel is tiny, higher requirements are put forward for accurate isolation and efficient integration between pixels in the manufacturing process, especially in the application of high-density integration.

In the fabrication of the micro-LED array, wafer bonding method is generally adopted to integrate multiple small-sized micro-LED chips onto a large-sized substrate to greatly improve the yield, reduce the rejection rate of a single chip and reduce the production cost. As far as the inventors know, dry etching processes (such as ICP etching (inductively coupled plasma etching)) are generally used for wafer bonding at present. However, the drying etching processes often have problems such as difficulty in etching depth control and uneven treatment, especially in the bonding of large-area wafers, the traditional dry etching is easy to lead to crosstalk and damage between pixels, which adversely affects the performance and the long-term stability of devices. In addition, after dry etching, thermal annealing is needed for repairing damage, which is easy to cause thermal damage.

### SUMMARY

An object of the present disclosure is to provide a micro-LED wafer bonding method to solve the technical problem above. On the basis of the traditional dry etching, the photoelectrochemical etching technology capable of performing fine etching at low temperature and low damage is added, which is adopted to repair damage on sidewalls of micro-LED pixels. It can also overcome other problems using dry etching such as difficulty in depth control, excessive damage, nonuniformity and thermal damage.

To achieve the object above, the present disclosure provides the following solutions: the present disclosure provides a micro-LED wafer bonding method, including the following steps:
step 1: preparing an epitaxial wafer and a driver substrate, wherein the epitaxial wafer includes a substrate layer and a pixel layer, the pixel layer includes a P polar face and an N polar face, the N polar face being in contact with the substrate layer, and the P polar face being separated from the substrate layer;
step 2: conducting vapor deposition of a metal layer on the P polar face of the pixel layer to form a p electrode, and conducting vapor deposition of a bonding layer on the driver substrate, wherein the bonding layer includes leveling areas and a bonding area for being electrically connected to the metal layer, the bonding area is arranged between the leveling areas, and at least the bonding area is made of a metal material in both the bonding area and the leveling areas;
step 3: bonding the metal layer as the p electrode with the bonding layer on the driver substrate, and peeling off the substrate layer;
step 4: forming individual micro-LED pixels on the pixel layer by dry etching;
step 5: conducting vapor deposition of metal Ti on N polar faces of the micro-LED pixels to obtain a hard mask, and repairing side walls of the micro-LED pixels by photoelectrochemical etching;
step 6: removing the metal Ti, and conducting vapor deposition of a first passivation layer, wherein the first passivation layer covers the micro-LED pixels and the metal layer;
step 7: forming a first opening in the first passivation layer at an area between the micro-LED pixels;
step 8: etching away the metal material in the bonding layer by drying etching;
step 9: conducting vapor deposition of a second passivation layer, wherein the second passivation layer covers the first opening, and forming a second opening in the second passivation layer on N polar faces of the micro-LED pixels; and
step 10: conducting vapor deposition of an interconnection layer, wherein the interconnection layer covers the second passivation layer and the second opening; and the interconnection layer and the driver substrate are interconnected to obtain an n electrode.

Compared with the prior art, some embodiments of the present disclosure have the following technical effects:
In the micro-LED wafer bonding method provided by the present disclosure, the photoelectrochemical etching technology is introduced on the basis of the traditional dry etching, the dry etching is firstly used for preliminary etching to form individual micro-LED pixels, and then the photoelectrochemical etching is adopted to repair and correct sidewalls of the micro-LED pixels. The photoelectrochemical etching could realize fine etching at the conditions of low temperature and low damage, thus avoiding the problems of excessive damage or unevenness existed in the traditional etching process. Compared with the traditional method by adopting the dry etching in the whole process, the photoelectrochemical etching not only could improve the etching accuracy to effectively achieve pixel isolation to reduce the damage of etching to materials, but also could complete the etching within a short time to improve the production efficiency. Moreover, the photoelectrochemical etching is carried out at a lower temperature, and thus thermal damage that may be caused in the traditional etching process could also be avoided.

### BRIEF DESCRIPTION OF THE DRAWINGS

To describe the technical solutions of the embodiments of the present disclosure or in the prior art more clearly, the following briefly introduces the illustrative drawings required for describing the embodiments. Apparently, the illustrative drawings in the following description show merely some embodiments of the present disclosure, and those of ordinary skill in the art may still derive other drawings from these accompanying drawings without creative efforts.

FIG. 1 shows a schematic diagram of an overall process in a micro-LED wafer bonding method according to one or more embodiments;

FIG. 2 shows a sectional view of a wafer bonding process in a micro-LED wafer bonding method according to one or more embodiments;

FIG. 3 shows a sectional view of a drying etching process in a micro-LED wafer bonding method according to one or more embodiments;

FIG. 4 shows a sectional view of a metal Ti deposition process in a micro-LED wafer bonding method according to one or more embodiments;

FIG. 5 shows a sectional view of a photoelectrochemical etching process in a micro-LED wafer bonding method according to one or more embodiments;

FIG. 6 shows a sectional view of a metal Ti removing process in a micro-LED wafer bonding method according to one or more embodiments;

FIG. 7 shows a sectional view of a first passivation process in a micro-LED wafer bonding method according to one or more embodiments;

FIG. 8 shows a sectional view of a first hole forming process in a micro-LED wafer bonding method according to one or more embodiments;

FIG. 9 shows a sectional view of a metal etching process in a micro-LED wafer bonding method according to one or more embodiments;

FIG. 10 shows a sectional view of a second passivation process in a micro-LED wafer bonding method according to one or more embodiments;

FIG. 11 shows a sectional view of a second hole forming process in a micro-LED wafer bonding method according to one or more embodiments;

FIG. 12 shows a sectional view of a deposition process of an interconnection layer in a micro-LED wafer bonding method according to one or more embodiments;

FIG. 13 shows a top view of FIG. 7;

FIG. 14 shows a top view of FIG. 8;

FIG. 15 shows a top view of FIG. 11.

Reference signs in the figures are as follows: 1 represents a substrate layer; 2 represents an N-GaN layer; 3 represents an MQW layer; 4 represents a P-GaN layer; 5 represents a metal layer; 6 represents leveling area(s); 7 represents a bonding area; 8 represents a driver substrate; 9 represents a metal Ti; 10 represents a first passivation layer; 11 represents a first opening; 12 represents a second passivation layer; 13 represents a second opening; 14 represents an interconnection layer.

### DETAILED DESCRIPTION OF THE EMBODIMENTS

The following clearly and completely describes the technical solutions in the embodiments of the present disclosure in conjunction with the accompanying drawings in the embodiments of the present disclosure. Apparently, the described embodiments are merely a part rather than all of the embodiments of the present disclosure. All other embodiments obtained by a person of ordinary skill in the art based on the embodiments of the present disclosure without creative efforts shall fall within the scope of the present disclosure.

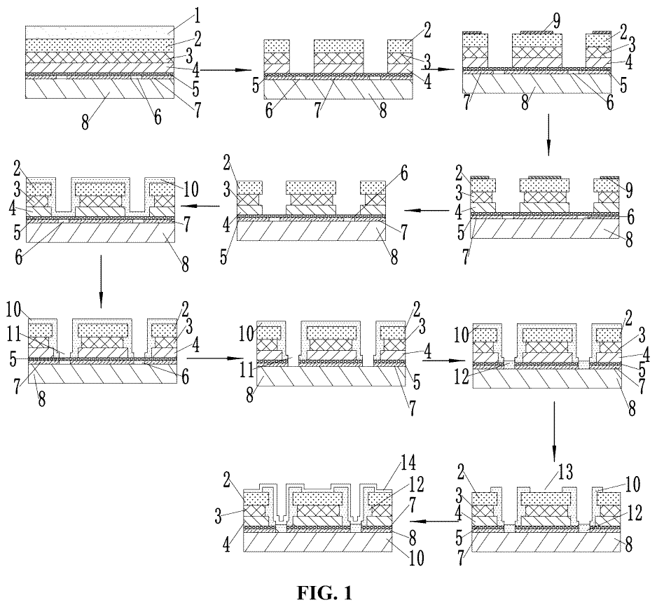

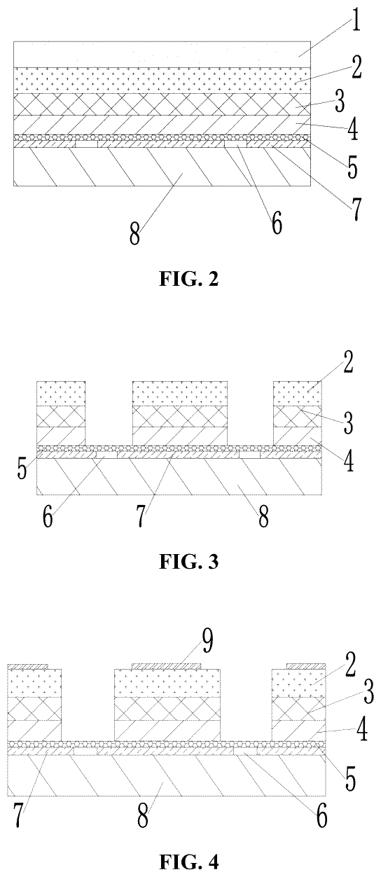

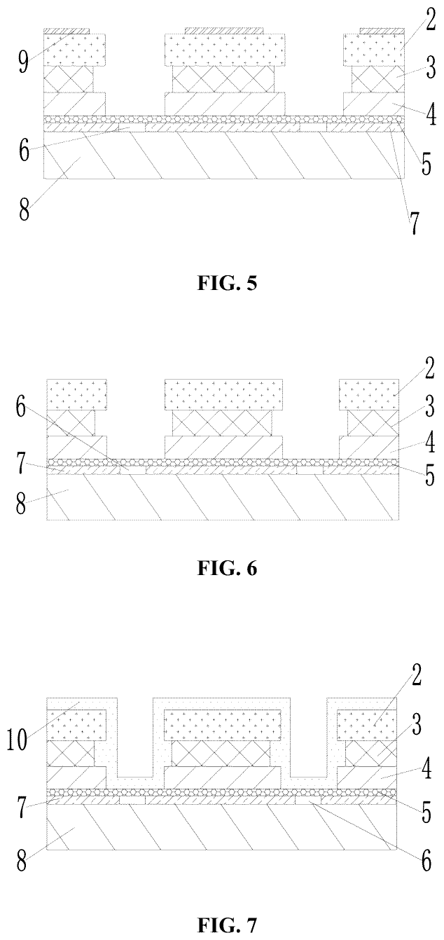

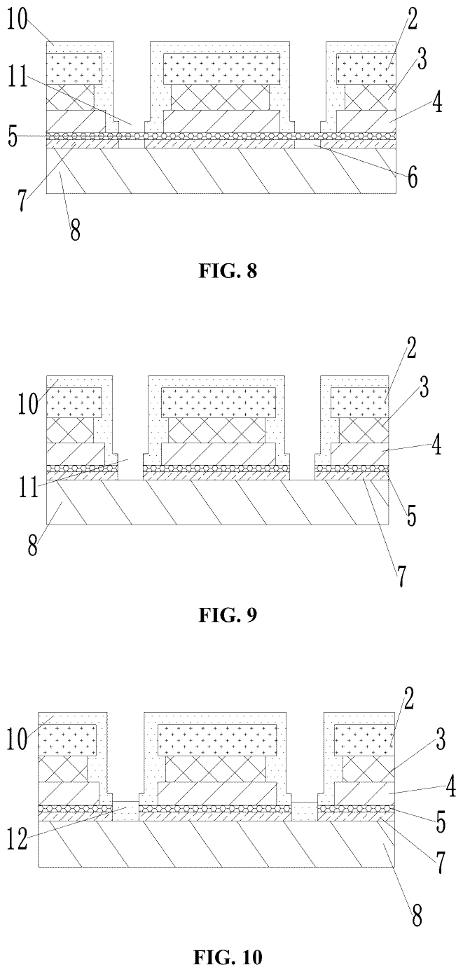

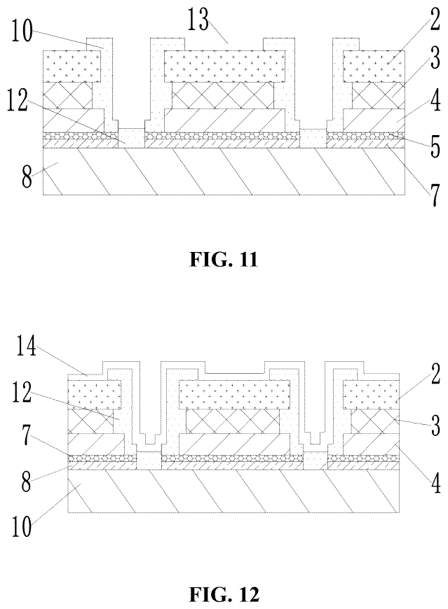

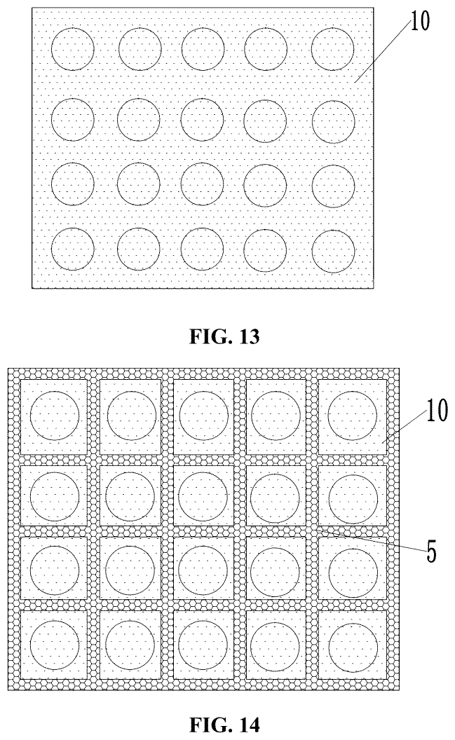

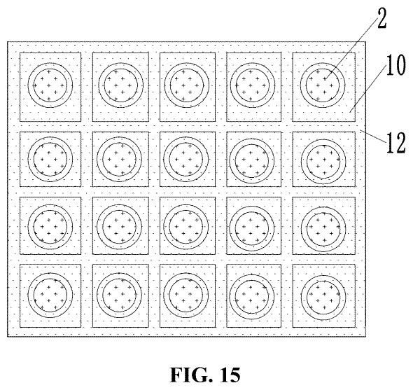

This embodiment provides a micro-LED wafer bonding method, as shown in FIG. 1 to FIG. 15, including the following steps:
step 1: an epitaxial wafer and a driver substrate 8 are prepared, where the epitaxial wafer includes a substrate layer 1 and a pixel layer, the pixel layer includes a P polar face and an N polar face, the N polar face is in contacted with the substrate layer 1, and the P polar face is separated from the substrate layer 1;
step 2: a metal layer 5 is vapor deposited on the P polar face of the pixel layer to form a p electrode, and a bonding layer is vapor deposited on the driver substrate 8, where the bonding layer includes leveling area(s) 6 and a bonding area 7, the bonding area 7 is used for being electrically connected to the metal layer 5, the bonding area 7 is arranged between the leveling area(s) 6, the bonding area 7 is used for being electrically connected to the metal layer 5, at least the bonding area 7 is made of a metal material in both the bonding area and the leveling areas, that is to say, the leveling area(s) 6 may also be made of the metal material, or a nonmetal material, and as the P electrode and the bonding area 7 are connected face to face, the leveling area(s) 6 is designed to ensure the planarization of the bonding layer;
step 3: the metal layer 5 is bonded with the bonding layer, and then the substrate layer 1 is peeled off;
step 4: individual micro-LED pixels are formed by etching the pixel layer by dry etching, which is preliminary etching;
step 5: metal Ti 9 is vapor deposited on N polar faces of the micro-LED pixels to obtain a hard mask, and sidewalls of the micro-LED pixels are repaired by photoelectrochemical etching;
step 6: the metal Ti 9 is removed, and a first passivation layer 10 is vapor deposited, where the first passivation layer 10 covers the micro-LED pixels and the metal layer 5;
step 7: a first opening 11 is formed in the first passivation layer 10 at an area between the micro-LED pixels;
step 8: the metal material in the bonding layer is etched away by drying etching, that is to say, if the leveling area(s) 6 is made of the metal material, both the leveling area(s) 6 and the bonding area 7 are etched away, and if the leveling area(s) 6 is made of the nonmetal material, only the bonding area 7 is etched away;
step 9: a second passivation layer 12 is vapor deposited, where the second passivation layer 12 covers the first passivation layer 10 and the first opening 11, and a second opening 13 is formed in the second passivation layer 12 on N polar faces of the micro-LED pixels; and
step 10: an interconnection layer 14 is vapor deposited, which covers the second passivation layer 12 and the second opening 13, and the interconnection layer 14 and the driver substrate 8 are interconnected to obtain an n electrode.

In the micro-LED wafer bonding method, the dry etching is firstly adopted for preliminary etching to form individual micro-LED pixels, and then the photoelectrochemical etching is used to repair the damage on the micro-LED pixels. The photoelectrochemical etching is a high-precision etching process, which combines the advantages of illumination and electrochemical reaction, which could achieve more uniform and accurate etching, accurately control etching depth and pixel isolation, reduce the damage of the sidewall, reduce the non-radiative recombination on the sidewall of the micro-LED chip, effectively improve the electrical isolation between pixels, and improve the stability of wafer bonding, thus avoiding the problems of difficulty in etching depth control, uneven processing and the like. Moreover, the photoelectrochemical etching could also be carried out at a lower temperature, thus avoiding possible thermal damage, and further improving the yield and productivity of the whole manufacturing process; and due to the characteristics of low damage and short treatment time of the photoelectrochemical etching, the production process is optimized, and the manufacturing cost is lowered.
Note: micro-LED is a micro light emitting diode.

In an embodiment, as shown in FIG. 1 to FIG. 15, the pixel layer includes an N-GaN layer 2, an MQW layer 3, and a P-GaN layer 4 arranged in sequence. The N-GaN layer 2 is in contact with the substrate layer 1, and the P-GaN layer 4 is separated from the substrate layer 1. Note: GaN is gallium nitride. The N-GaN layer means a gallium nitride layer is n-type, and the P-GaN layer means a gallium nitride layer is p-type. MQW is a multi-quantum well.

In one embodiment, as shown in FIG. 1 to FIG. 15, the substrate layer 1 is made of a silicon material or a sapphire material.

In one embodiment, as shown in FIG. 1 to FIG. 15, the leveling area(s) 6 is made of the metal material, a polymer material, or an oxide material. If the leveling area(s) 6 is made of the metal material, the leveling area(s) 6 and the bonding area 7 are both etched away in step 8. When the leveling area(s) is made of the metal material, which may be the same as that of the bonding area 7, and when the leveling area(s) 6 is made of the polymer material or the oxide material, it is considered as hybrid bonding, e.g., hybrid bonding of polyimide (PI)/metal, or hybrid bonding of SiO₂/Cu.

In one embodiment, as shown in FIG. 1 to FIG. 15, in step 6, the metal Ti 9 is removed by a wet process.

In one embodiment, as shown in FIG. 1 to FIG. 15, the first passivation layer 10 and the second passivation layer 12 are both formed by silicon oxide deposition.

In one embodiment, as shown in FIG. 1 to FIG. 15, in step 7, the first opening 11 is formed by photolithography followed by etching.

In one embodiment, as shown in FIG. 1 to FIG. 15, in step 8, the second opening 13 formed by photolithography followed by etching.

In one embodiment, as shown in FIG. 1 to FIG. 15, the dry etching in step 4 is performed by an ICP etching process, and the dry etching in step 8 is performed by an IBE process.
Note: the ICP etching (Inductively Coupled Plasma Etching) is a technological process that uses a high-frequency electromagnetic field to excite a gas to generate plasma to achieve material removal through physical bombardment and chemical reaction. Its basic principle is that in a vacuum and low-pressure environment, the gas is excited by a radio frequency power supply to generate plasma, and ions and active particles in the plasma bombard the surface of the material and chemically react under the action of an electric field, thus removing the material.

The IBE process (Ion Beam Etching) is a physical etching process that uses a high-energy ion beam to bombard the surface of materials accurately and directionally to remove the material. The IBE etching process has strong directionality and could achieve fine machining of the surface of the material.

In one embodiment, as shown in FIG. 1 to FIG. 15, the interconnection layer 14 is a metal grid or ITO (indium tin oxide) film.
Note: The IBE process (Ion Beam Etching) is a physical etching process that uses a high-energy ion beam to bombard the surface of materials accurately and directionally to remove the material. The IBE etching process has strong directionality and could achieve fine machining of the surface of the material.

In one embodiment, as shown in FIG. 1 to FIG. 15, the interconnection layer 14 is a metal grid or ITO film. Note: ITO is indium tin oxide.

In one embodiment, as shown in FIG. 1 to FIG. 15, before step S1, the method further includes the following steps, and the following steps are mainly machine learning parts:
step 1: key data in a chip bonding process is collected, including four main input parameters: a pressure, a temperature, a duration, and a warping level, and corresponding output parameters: a bonding force, and a yield.
step 2: the data is cleaned, and a missing value is processed by mean filling or similar sample-based interpolation;
step 3: input features are subjected to standardized processing, for example, Z-score standardization is used;
step 4: the preprocessed data is trained using a Gaussian process regression model;
step 5: an appropriate kernel function is selected to capture a correlation between the input parameters and provide a confidence interval of a prediction result;
step 6: the performance of the model is assessed using a cross-validation method;
step 7: a hyperparameter of the kernel function is optimized by maximizing a marginal likelihood function;
step 8: the prediction performance of the Gaussian process regression model is comprehensively measured by using assessment indexes such as mean square error (MSE), mean absolute error (MAE) and determination coefficient (R²);
step 9: the trained Gaussian process regression model is combined with Bayesian optimization algorithm to find an input parameter combination capable of maximizing bonding yield; and
step 10: the input parameter combination capable of maximizing the bonding yield is determined to optimize the production process.

Specific embodiments are used herein for illustration of the principles and embodiments of the present disclosure. The description of the embodiments is merely used to help illustrate the method and its core principles of the present disclosure. In addition, those of ordinary skill in the art could make various modifications in terms of specific embodiments and scope of application in accordance with the teachings of the present disclosure. In conclusion, the content of this specification shall not be construed as a limitation to the present disclosure

What is claimed is:

1. A micro-light-emitting diode (micro-LED) wafer bonding method, comprising:
step 1: preparing an epitaxial wafer and a driver substrate, wherein the epitaxial wafer comprises a substrate layer and a pixel layer, the pixel layer comprises a P polar face and an N polar face, the N polar face being in contact with the substrate layer, and the P polar face being separated from the substrate layer;
step 2: conducting vapor deposition of a metal layer on the P polar face of the pixel layer to form a p electrode, and conducting vapor deposition of a bonding layer on the driver substrate, wherein the bonding layer comprises leveling areas and a bonding area for being electrically connected to the metal layer, the bonding area is arranged between the leveling areas, and at least the bonding area is made of a metal material in both the bonding area and the leveling areas;
step 3: bonding the metal layer with the bonding layer, and peeling off the substrate layer;
step 4: forming individual micro-LED pixels on the pixel layer by dry etching;
step 5: conducting vapor deposition of metal Ti on N polar faces of the micro-LED pixels to obtain a hard mask, and repairing side walls of the micro-LED pixels by photoelectrochemical etching;
step 6: removing the metal Ti, and conducting vapor deposition of a first passivation layer, wherein the first passivation layer covers the micro-LED pixels and the metal layer;
step 7: forming a first opening in the first passivation layer at an area between the micro-LED pixels;
step 8: etching away the metal material in the bonding layer by drying etching;
step 9: conducting vapor deposition of a second passivation layer, wherein the second passivation layer covers the first opening, and forming a second opening in the second passivation layer on N polar faces of the micro-LED pixels; and
step 10: conducting vapor deposition of an interconnection layer, wherein the interconnection layer covers the second passivation layer and the second opening, and the interconnection layer and the driver substrate are interconnected to obtain an n electrode.

2. The micro-LED wafer bonding method as claimed in claim 1, wherein the pixel layer comprises an N-GaN layer, an MQW (multi-quantum well) layer, and a P-GaN layer arranged in sequence, the N-GaN layer is in contact with the substrate layer, and the P-GaN layer is separated from the substrate layer.

3. The micro-LED wafer bonding method as claimed in claim 1, wherein the substrate layer is made of a silicon material or a sapphire material.

4. The micro-LED wafer bonding method as claimed in claim 1, wherein the leveling areas are each made of one material selected from the group consisting of a metal material, a polymer material, and an oxide material.

5. The micro-LED wafer bonding method as claimed in claim 1, wherein in step 6, the metal Ti is removed by a wet process.

6. The micro-LED wafer bonding method as claimed in claim 1, wherein the first passivation layer and the second passivation layer are both formed by deposition of silicon oxide.

7. The micro-LED wafer bonding method as claimed in claim 1, wherein in step 7, the first opening is formed by photolithography followed by etching.

8. The micro-LED wafer bonding method as claimed in claim 1, wherein in step 8, the second through hole is formed by photolithography followed by etching.

9. The micro-LED wafer bonding method as claimed in claim 1, wherein the dry etching in step 4 is performed by an ICP (inductively coupled plasma) etching process, and the dry etching in step 8 is performed by an IBE (ion beam etching) process.

10. The micro-LED wafer bonding method as claimed in claim 1, wherein the interconnection layer is one selected from the group consisting of a metal grid and an ITO (indium tin oxide) film.

11. The micro-LED wafer bonding method as claimed in claim 2, wherein the substrate layer is made of a silicon material or a sapphire material.

12. The micro-LED wafer bonding method as claimed in claim 8, wherein the dry etching in step 4 is performed by an ICP (inductively coupled plasma) etching process, and the dry etching in step 8 is performed by an IBE (ion beam etching) process.
